(19) United States
(12) Patent Application Publication
(10) Pub. No.: US 2003/0061990 A1
(43) Pub. Date: Apr. 3, 2003

(54) CVD diameter control with particle separation

(75) Inventor: Christopher D. Shay, Hickory, NC (US)

Correspondence Address: SUGHRUE MION ZINN MACPEAK & SEAS, PLLC, 2100 Pennsylvania Avenue, NW, Washington, DC, 20037-3213, US

(73) Assignee: ALCATEL

(21) Appl. No.: 09/968,848

(22) Filed: Oct. 3, 2001

(51) Int. Cl. C23C 16/00

(52) U.S. Cl. 118/715

(57) ABSTRACT

An optical fiber preform fabricating device is disclosed. The device includes a particle remover for removing soot from a carrier gas, the soot being particles that are not deposited on a substrate tube. The device also includes a soot collector communicating with the particle remover for containing the soot removed by the particle remover. A control valve communicates with the particle remover, and adjusts a pressure within the substrate tube.

### BACKGROUND OF THE INVENTION

1. Field of the Invention

The present invention relates to fabrication of an optical fiber preform. More specifically, the present invention relates to removing soot particles and controlling the diameter of the preform during a chemical vapor deposition (CVD) process.

2. Description of the Related Art

The present invention is useable with a process for manufacturing a preform from which optical fibers may be drawn. Such optical fibers are used for transmitting optical signals in telecommunications applications. The preform may be manufactured by a variety of methods, including the CVD process in which glassy particles (soot) are deposited onto the inside wall of a glass substrate tube. The soot generally comprises silica that has been doped to provide a desired index of refraction. During the deposition process the soot is passed longitudinally through the glass tube by a carrier gas and a heat source is passed over the outside of the glass tube. The heat from the heat source sinters the soot to provide a homogenous glass layer. Heating the tube softens the tube and the pressure must be controlled inside the tube to achieve a desired tube diameter. Without a constant target pressure, the tube diameter may detrimentally increase, decrease, or otherwise deform, thereby affecting the quality of the preform and the resulting fibers drawn from the preform.

Methods for controlling the pressure inside the tube are currently unsatisfactory. For example, known methods of controlling the pressure inside the tube include using a valve to control the flow of the soot and carrier gas, and introducing a counterflow of a gas, such as oxygen, nitrogen, or other inert gas, at a downstream position relative to the flow of soot. In either example, a back-pressure is thereby created in the tube. However, such prior art methods suffer from several drawbacks including, for example, “blowback” caused by the valve sticking in a “closed” position, or imbalances that develop between the tube inlet and exit pressures. Specifically, the valve may become clogged with soot and is prevented from opening properly, some other obstruction within the apparatus may develop, or the counterflow gas may “spike” due to an unintended control loop command. Regardless of the cause, the pressure imbalance must eventually correct itself, often to the detriment of the preform. Short-term imbalances such as those described above can result in large soot agglomerations being propelled backwards into the substrate tube. These instances of blow-back cause imperfections, such as bubbles, that reduce the quality of the preform. Long-term pressure imbalances can cause catastrophic failures if the over-pressurization persists for a sufficient amount of time to cause the preform to burst.

In view of the preceding discussion, a need exists for an apparatus and method for controlling the pressure in the glass substrate tube without causing imperfections or preform bursting during a CVD process.

### ASPECTS OF THE INVENTION

In a first aspect of the present invention an optical fiber preform fabricating device is provided. The preform fabricating device includes a particle remover for removing soot from a carrier gas, the soot being particles that are not deposited on a substrate tube. A soot collector communicates with the particle remover and contains the soot removed by the particle remover. Further, a control valve communicates with the particle remover. The control valve adjusts a pressure within the substrate tube.

In a second aspect of the present invention an optical fiber preform fabricating device is provided. The preform fabricating device includes a particle remover, a collector and a valve. The particle remover removes soot from a carrier gas, the soot being particles that are not deposited on a substrate tube. The collector communicates with the particle remover and contains the soot removed by the particle remover. The valve adjusts a pressure within the substrate tube.

In another aspect of the present invention, a method for fabricating a preform is provided. The method includes the step of removing soot from a carrier gas before the carrier gas passes through a valve, the soot being particles that are not deposited on a substrate tube. The method also includes the step of controlling a pressure and a flow rate of the carrier gas within the substrate tube.

These and other aspects, features and advantages of the present invention will become apparent from the following detailed description of the preferred embodiments taken in conjunction with the accompanying drawings.

### BRIEF DESCRIPTION OF THE DRAWINGS

FIG. 1 is a plan view of a preferred embodiment of the present invention.

FIG. 2 is a plan view of features of the preferred embodiment of the present invention.

FIG. 3 is a cross-sectional view of a glass tube during a CVD operation.

### DETAILED DESCRIPTION OF THE INVENTION

As explained below in detail, preferred embodiments of the present invention provide an apparatus and method for removing soot particles from a carrier gas and for controlling the diameter of a glass substrate tube during a CVD process. Of course the invention should not be limited solely to such features. These and other features of the preferred embodiments of the present invention are discussed below in detail.

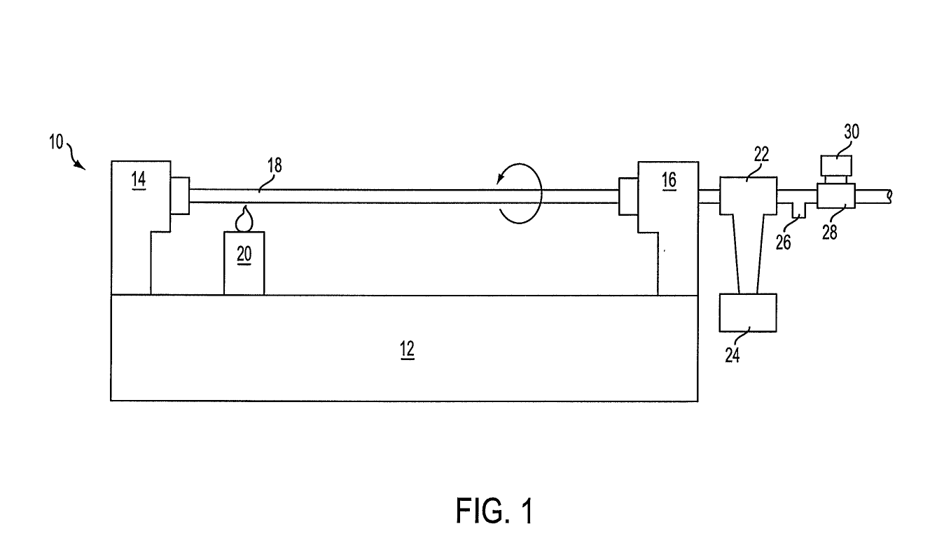

A deposition apparatus 10 for performing a CVD operation in accordance with the present invention is illustrated in FIG. 1. The deposition apparatus 10 includes a glass working lathe 12 having a headstock 14 and a tailstock 16. The headstock 14 and tailstock 16 support a substrate tube 18 in such a manner that the substrate tube 18 may be rotated about its longitudinal axis. The substrate tube 18 is mounted in the headstock 14 and tailstock 16 such that a stream of reactants, collectively referred to as soot, entrained in a carrier gas passes longitudinally through the substrate tube 18. Specifically, the reactants and the carrier gas are fed through the headstock 14, they react and form soot particles in the substrate tube 18, and the effluent, which includes carrier gasses and undeposited soot, flows through the tail stock 16. The soot includes dopants, such as germanium, for affecting optical properties of the finished preform. In a preferred embodiment the soot may also include phosphorous, fluorine, or any other desired materials.

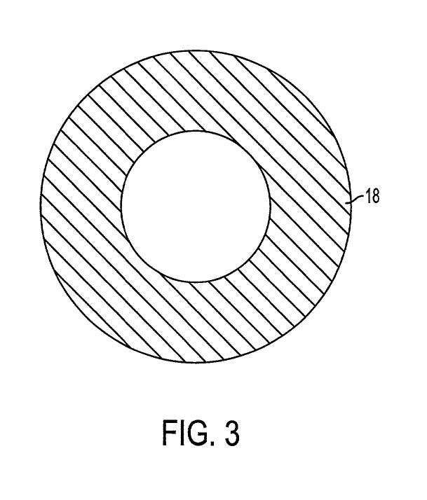

The glass working lathe 12 also includes a heat source 20 such as a hydrogen and oxygen burner that directs heat against the substrate tube 18 in a defined heated area. The heated area creates a reaction zone within the substrate tube 18. The heat source 20 is moved co-axially along the rotating substrate tube 18 during the CVD process, thereby causing the reaction zone to move along the substrate tube 18. Soot is deposited onto the inner surface of the substrate tube 18 within and downstream of the reaction zone and is fused into a homogenous layer by the heat from the heat source 20. Moving the heat source 20 along the substrate tube 18 is repeated one or more times to deposit additional layers of soot onto the inner wall of the substrate tube 18. The wall of the substrate tube 18 is thereby increased to a desired thickness. See FIG. 3.

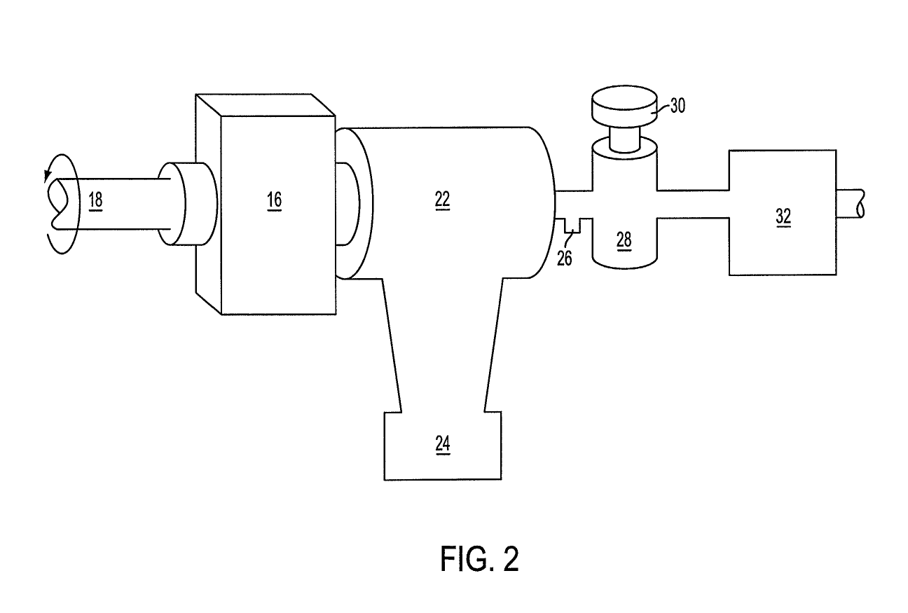

Not all of the soot is deposited onto the wall of the substrate tube 18 when the soot and carrier gas mixture passes through the reaction zone. The remaining soot and carrier gas mixture exits the substrate tube 18 through the tailstock 16. As shown in FIGS. 1 and 2, the soot and gas mixture passes through the tailstock 16 and enters a particle removing device 22 for removing the soot particles from the gas stream. Soot particles are thereby prevented from passing back into the substrate tube 18 if there is any inadvertent counterflow of the carrier gas. The particle removing device 22 may be any suitable mechanism for removing the soot particles. Examples of such a device include separators such as a cyclone, impaction box, impingement separator, filter, scrubber, thermal separator or a settling chamber. In a preferred embodiment, a soot collector 24 communicates with the particle removing device 22 and collects the soot particles for later disposal or recycling. The soot collector 24 may be configured as a removable drawer, a bag or box, or any other easily replaceable or easily cleanable structure. Of course the invention is not limited to the above-described structures, and other devices for separating and holding the soot particles are also considered to be within the scope of the present invention.

In the preferred embodiment, the gas stream exits the particle removing device 22 then passes across a pressure transducer 26. The pressure transducer 26 may be any known pressure transducer. The pressure transducer 26 detects the pressure of the carrier gas as it exits the particle removing device 22 and, from this detected pressure, the pressure inside the substrate tube 18 may be closely approximated. The position shown in FIGS. 1 and 2 for pressure transducer 26 is only one example. Other ports for pressure measurement can be placed at various points within the system. Also, for increased accuracy, multiple pressure transducers 26 may be used to detect the pressure at multiple points within the deposition apparatus 10. For example, a pressure transducer 26 may be incorporated into one or more of the particle removing device 22, the tailstock 16 and the headstock 14. The pressure within the substrate tube 18 may thus be accurately approximated in accordance with measurements from one or more of the pressure transducers 26.

As shown in FIG. 2, the carrier gas passes through a control valve 28 after passing across the pressure transducer 26. The control valve 28 controls the flow rate of the gas stream as the gas stream passes through the deposition apparatus 10 and thereby controls the gas pressure inside the substrate tube 18. Specifically, the control valve 28 is adjusted by a controller 30 to regulate the flow rate of the gas in accordance with the pressure detected by the pressure transducer 26. By way of example, the controller 30 may include a central processing unit and memory with executable code for manipulating data received from the pressure transducer 26 and for outputting a corresponding control signal to the control valve 28. The control valve 28 may be any conventional pressure proportioning or flow control valve assembly, or any other variable aperture device useable for regulating the flow of gas and/or pressure in response to a control signal or other input. The controller 30 controls the control valve 28 such that the pressure of the carrier gas inside substrate tube 18 reaches and maintains a desired value. The pressure of the carrier gas in the substrate tube 18 is decreased by controlling the control valve 28 to adjust to a more open position. The flow rate of the carrier gas through the control valve 28 and out of the substrate tube 18 is thereby increased, and the pressure within the substrate tube 18 is decreased. Alternatively, the pressure of the carrier gas in the substrate tube 18 is increased by controlling the control valve 28 to adjust to a more closed position. The flow rate of the carrier gas through the control valve 28 and out of the substrate tube 18 is thereby decreased, and the pressure within the substrate tube 18 increases. In accordance with a preferred embodiment of the present invention, the control valve 28 does not suffer performance degradation caused by soot accretion. Instead, the particle removing device 22 removes the soot from the carrier gas before the carrier gas enters the control valve 28, and the control valve 28 is thus protected from becoming clogged or fouled. Blow-back of gas into the substrate tube 18 resulting from the control valve 28 sticking in the closed position, leading to an imbalance in gas pressures, is thereby prevented. If more than one pressure transducer 26 is used to monitor pressures within the deposition apparatus 10, the controller 30 adjusts the control valve 28 in accordance with the pressures detected by each of the pressure transducers 26, or by pre-determined combinations of the pressure transducers 26.

The gas stream exits the control valve 28 and passes to downstream components such as a scrubber 32 for further removing components from the carrier gas. For example, the scrubber 32 removes any remaining particles, chlorine gases, germanium, silica, byproducts of reactions in the reaction zone, or any other predetermined components of the carrier gas.

As described above in detail, a preferred embodiment of the present invention prevents fouling of the control valve 28, and prevents blow-back of the carrier gas and soot into the substrate tube 18. In addition to preventing fouling and blow-back, a preferred embodiment of the present invention also controls the diameter of the substrate tube 18. Specifically, the wall of the substrate tube 18 in the reaction zone is softened when the wall is heated by the heat source 20. The pressure of the carrier gas is detected by one or more of the pressure transducers 26 and the pressure within the reaction zone of the substrate tube 18 is approximated. The controller 30 then controls the control valve 28 to increase or decrease the flow rate of the carrier gas through the substrate tube 18 in accordance with the pressure detected by the pressure transducer. The difference in pressure between the carrier gas in the substrate tube 18 and ambient pressure outside the substrate tube 18 causes the softened walls of the substrate tube 18 to expand or collapse to reach a desired diameter. Further, unwanted and potentially dangerous expansion of the substrate tube 18 resulting from obstructions caused by soot build-up in the exhaust apparatus is prevented in the manner previously discussed. Specifically, the control valve 28 is prevented from becoming fouled, and an unwanted pressure differential does not occur, because the particle removing device 22 removes unwanted soot particles from the carrier gas stream before the carrier gas stream passes through the control valve 28. In the foregoing manner the diameter of the substrate tube 18 in the reaction zone is reliably controlled. As the heat source 20 moves along the substrate tube 18 the reaction zone also moves along the substrate tube 18. The diameter of the entire substrate tube 18 is then controlled in the foregoing manner.

Although specific embodiments of the present invention have been described above in detail, it will be understood that this description is merely for illustration purposes. Various modifications of and equivalent structures corresponding to the disclosed aspects of the preferred embodiments in addition to those described above may be made by those skilled in the art without departing from the spirit of the present invention which is defined in the following claims, the scope of which is to be accorded the broadest interpretation so as to encompass such modifications and equivalent structures.

I claim:

1) An optical fiber preform fabricating device, comprising:
a particle remover for removing soot from a carrier gas, the soot being particles that are not deposited on a substrate tube;
a soot collector communicating with said particle remover for containing the soot removed by said particle remover; and
a control valve communicating with said particle remover, said control valve for adjusting a pressure within the substrate tube.

2) The optical fiber preform fabricating device recited in claim 1, further comprising a pressure transducer for monitoring a pressure of the carrier gas.

3) The optical fiber preform fabricating device recited in claim 2, further comprising a controller for controlling said control valve in accordance with the pressure monitored by said pressure transducer.

4) The optical fiber preform fabricating device recited in claim 1, further comprising a removing device communicating with said control valve, said removing device for removing components from the carrier gas.

5) The optical fiber preform fabricating device recited in claim 1, further comprising a headstock and a tailstock communicating with said particle remover and the substrate tube, said headstock and said tailstock cooperating to rotate the substrate tube about the substrate tube's longitudinal axis.

6) The optical fiber preform fabricating device recited in claim 5, further comprising a heater for heating the substrate tube as said headstock and said tailstock rotate the substrate tube.

7) An optical fiber preform fabricating device, comprising:
particle remover means for removing soot from a carrier gas, the soot being particles that are not deposited on a substrate tube;
collector means communicating with said particle remover means for containing the soot removed by said particle remover means; and
valve means for adjusting a pressure within the substrate tube.

8) The optical fiber preform fabricating device recited in claim 7, further comprising monitoring means communicating with said valve means for monitoring a pressure of the carrier gas.

9) The optical fiber preform fabricating device recited in claim 8, further comprising control means for controlling said valve means in accordance with the pressure monitored by said monitoring means.

10) The optical fiber preform fabricating device recited in claim 7, further comprising remover means communicating with said valve means, said remover means for removing components from the carrier gas.

11) The optical fiber preform fabricating device recited in claim 7, further comprising headstock means and tailstock means communicating with said particle remover means and the substrate tube, said headstock means and said tailstock means cooperating to rotate the substrate tube about the substrate tube's longitudinal axis.

12) The optical fiber preform fabricating device recited in claim 11, further comprising heating means for heating the substrate tube as said headstock means and said tailstock means rotate the substrate tube.

13) A method for fabricating a preform, comprising the steps of:
removing soot from a carrier gas before the carrier gas passes through a valve, the soot being particles that are not deposited on a substrate tube; and
controlling a pressure and a flow rate of the carrier gas within the substrate tube.

14) The method for fabricating a preform recited in claim 13, further comprising the step of monitoring a pressure of the carrier gas during removal of the soot.

15) The method for fabricating a preform recited in claim 13, further comprising the step of controlling a flow rate of the carrier gas in accordance with the pressure monitored in said monitoring step.

16) The method for fabricating a preform recited in claim 13, further comprising the step of heating the substrate tube to fuse soot onto the substrate tube.

17) The method for fabricating a preform recited in claim 13, further comprising the step of removing components of a gas stream after said removing step.

18) The method for fabricating a preform recited in claim 13, further comprising the step of controlling a diameter of the substrate tube in accordance with the pressure monitored in said monitoring step.
